(19) United States
(12) Patent Application Publication
(10) Pub. No.: US 2012/0194194 A1
(43) Pub. Date: Aug. 2, 2012

(54) NMR Sample Containers

(75) Inventor: Gregory B. Norell, Morganton, NC (US)

(73) Assignee: Norell, Inc., Landisville, NJ (US)

(21) Appl. No.: 13/017,691

(22) Filed: Jan. 31, 2011

(51) Int. Cl. G01N 1/00; G01R 33/44

(52) U.S. Cl. 324/321

(57) ABSTRACT

A kit and methods of using including a package with at least one NMR tube comprising an elongate cylindrical body with an open proximal end and a band around an outside of the cylindrical body, the band positioned adjacent the open proximal end and having a width extending along a length of the elongate cylindrical body. The kit also including at least one closure configured to slidably engage the outside of the elongate cylindrical body so that when the closure is fully placed on the NMR tube, a distal end of the closure extends a length along the cylindrical body and is within about the width of the band.

### BACKGROUND

This application is generally related to sample containers for placing a sample for measurement of a property of the sample in an instrument, and more particularly, to sample tubes and closures for Nuclear Magnetic Resonance (NMR) samples.

Nuclear Magnetic Resonance spectroscopy is widely used in chemical studies for structure determination as well as presence, absence or concentration of a particular component in a sample. An NMR spectrum of a sample is generally determined by placing the sample in an elongate sample tube, placing the tube containing the sample in the field of a powerful magnet and selectively irradiating the sample with preselected radiofrequency signals and recording the effects of these signals on the sample. The sample tubes are formed from glass and are supplied in several sizes ranging from diameters of 1 mm to about 10 mm with lengths of about four inches to about seven inches long. The resolution of the spectrometer may be adversely affected by asymmetries in the sample tube and its placement within the magnetic field and irradiation coils. Accordingly, users of NMR spectrometers seek sample tubes and holders that minimize asymmetry.

In an effort to “average-out” sample asymmetry, some spectrometers axially spin samples on which the spectrum is being determined. More recently, NMR spectrometers have the capability to average-out some sample asymmetry electronically without spinning, but sample placement and positioning in the sample chamber is still important to optimize the resolution of the spectrometer. These more recent NMR spectrometers also utilize the tube closure to suspend the sample axially in the sample chamber. Thus, tube closures, or caps, need to do more than just close the tube. When the samples are not spun, the coaxiality of the outer diameter, the closure and the inside diameter of the tube, if not consistent and precise, may adversely effect the quality of the spectrum obtained.

In many cases, the materials whose NMR spectrum is being determined are derived from expensive and difficult to repeat studies. Accordingly, if a sample is lost or degraded because of a malfunction of the sample closure or the tube, the user may experience a substantial and expensive delay in their study. Thus, although there are many types of NMR sample systems and tube closure devices available, there is still a need for an NMR sample system and closure which is reliable, simple to use and allows the user of an NMR spectrometer to fully utilize the resolution capability of the spectrometer and ensure that the closure has been fully seated on the NMR tube. This is especially the case where automated sample handling equipment is employed. Such a system and closure is disclosed herein.

### SUMMARY

Embodiments of the invention are directed to kits comprising a package, at least one NMR tube and at least one closure. The package has a support structure adapted to contain and separate elongate articles. The at least one NMR tube comprises an elongate cylindrical body with an open proximal end and a band around an outside of the cylindrical body. The band is positioned adjacent the open proximal end and has a width extending along a length of the elongate cylindrical body. The at least one closure is configured to slidably engage the outside of the elongate cylindrical body so that when the closure is fully placed on the NMR tube, a distal end of the closure extends a length along the cylindrical body and is within about the width of the band.

In some embodiments, when the closure is fully placed on the NMR tube, the distal end of the closure is about equal to a proximal edge of the band. In detailed embodiments, when the closure is fully placed on the NMR tube, the closure covers a portion of the band. In specific embodiments, wherein when the closure is fully placed on the NMR tube, the distal end of the closure is about equal to a distal edge of the band.

Additional embodiments of the invention are directed to methods of using an NMR tube. A closure having a hollow bore in a distal end is placed over an open proximal end of an NMR tube having an elongate cylindrical body with an outer diameter and a band around an outside surface of the elongate cylindrical body. The band has a width and is placed adjacent the open proximal end. The hollow bore of the closure has an diameter about equal to or lesser than about the outer diameter of the elongate body. A distally directed force is applied to the closure to cause the hollow bore to slide along the outside surface of the elongate cylindrical body to a length from the open proximal end, so that when the closure is fully placed on the NMR tube, the distal end of the closure is within about the width of the band.

In some embodiments, resistance to the distally directed force remains about constant throughout pushing the closure along the elongate cylindrical body from the open proximal end until the closure cannot be pushed further. In various embodiments, resistance to the distally directed force varies throughout pushing the closure along the elongate cylindrical body from the open proximal end until the closure cannot be pushed further.

In one or more embodiments, after the closure is fully placed on the NMR tube, the distal end of the closure is adjacent a proximal edge of the band. In detailed embodiments, after the closure is fully placed on the NMR tube, the distal end of the closure covers at least a portion of the band. In specific embodiments, after the closure is fully placed on the NMR tube, the distal end of the closure covers the entire band.

Some embodiments of the method further comprise adding a sample to the NMR tube before placing the closure over the proximal open end of the NMR tube. In detailed embodiments, the sample is added to the NMR tube through an opening in the closure after the closure has been fully placed on the NMR tube. The opening extends axially through the closure so that after the closure has been fully placed onto the NMR tube, a sample can be placed into the NMR tube through the opening. In specific embodiments, the opening comprises a septum. In one or more embodiments, the NMR tube is placed into a sample spinner.

In some embodiments, the at least one closure has a color and the band on the at least one NMR tube is colored. In detailed embodiments, the color of the closure is the same as the color of the band. In specific embodiments, the color of the closure is different than the color of the band.

The present invention also contemplates apparatus that includes a NMR cylindrical tube having a closed end and an open end, a cap having a hollow bore sized to securely fit over the open end of the NMR cylindrical tube and a band around the outside of the NMR cylindrical tube. The band is positioned adjacent the open end of the NMR cylindrical tube such that when a top portion of the hollow bore of the cap touches the open end of the NMR cylindrical tube, at least a portion of the band is visible.

### BRIEF DESCRIPTION OF THE DRAWINGS

FIG. 1 is an exploded partial cross-sectional perspective view of an NMR sample tube and closure in accordance with one or more embodiments of the invention;

FIG. 2 is a cross-sectional view of a sample tube and closure in accordance with one or more embodiments of the invention;

FIGS. 3A through 3C are cross-sectional views showing a closure being applied to a sample tube in accordance with one or more embodiments of the invention;

FIG. 4 is a cross-sectional view of a sample tube and closure in accordance with one or more embodiments of the invention;

FIG. 5 is a cross-sectional view of a sample tube and closure in accordance with one or more embodiments of the invention;

FIGS. 6A and 6B show cross-sectional views of a sample tube and closure in accordance with one or more embodiments of the invention;

FIG. 7 is a cross-sectional view of a sample tube and closure in accordance with one or more embodiments of the invention;

FIG. 8 is a cross-sectional view of a sample tube and closure in accordance with one or more embodiments of the invention;

FIG. 9 is an exploded partial cross-sectional view of a closure in accordance with one or more embodiments of the invention; and

FIG. 10 is an exploded perspective view of a kit in accordance with one or more embodiments of the invention.

Before describing several exemplary embodiments of the invention, it is to be understood that the invention is not limited to the details of construction or process steps set forth in the following description. The invention is capable of other embodiments and of being practiced or being carried out in various ways.

### DETAILED DESCRIPTION

Reference throughout this specification to “one embodiment,” “certain embodiments,” “one or more embodiments” or “an embodiment”, means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment”, in various places throughout this specification are not necessarily referring to the same embodiment of the invention. Furthermore, the particular features, structures, materials, or characteristics may be combined in any suitable manner in one or more embodiments.

In this specification and the appended claims, the term “proximal” refers to the direction away from the closed end of the sample tube and the term “distal” refers to the direction toward the closed end of the sample tube.

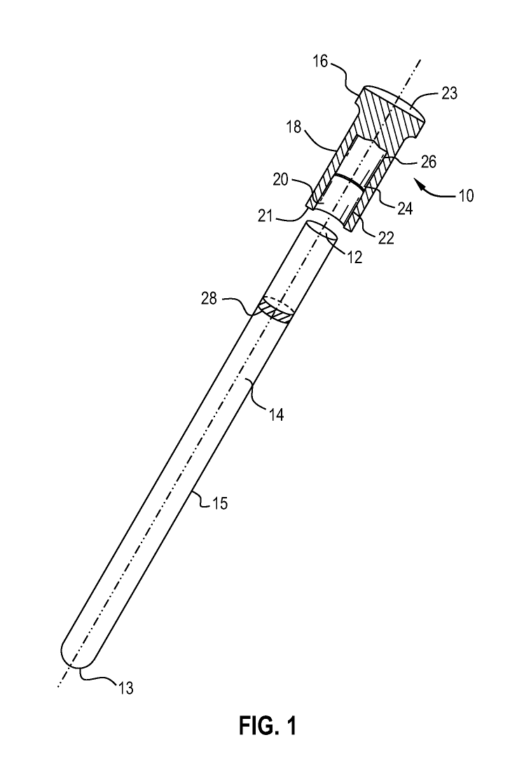

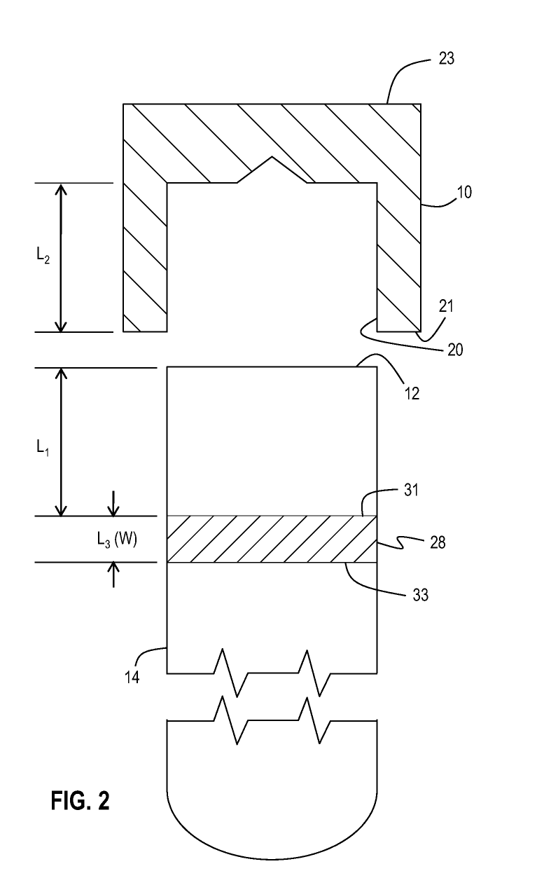

FIGS. 1 and 2 show an NMR sample tube 14 and selectively removable closure 10 in accordance with one or more embodiments of the invention. The NMR sample tube 14 has an elongate cylindrical body 15 with an open proximal end 12 and a closed distal end 13. A band 28 is around the outside of the cylindrical body 15 and is positioned adjacent the open proximal end 12 of the sample tube 14. The band 28 is positioned a length L₁ from the open proximal end 12 of the sample tube 14. The removable closure 10, also referred to as a cap, includes a hollow bore 20 extending a length L₂ from the distal end 21 of the closure 10 toward the proximal end 23 of the closure 10.

Referring to FIG. 2, the band 28 has a proximal edge 31 adjacent the open proximal end 12 of the tube. The proximal edge 31 is positioned a distance (length L₁) from the proximal end 12 and the band 28 extends a length L₃ along the sample tube 14. The length L₃, also referred to as the width W of the band 28, is defined as the distance between the proximal edge 31 and the distal edge 33 of the band 28. The width W may also be referred to as the length that the band 28 extends along the sample tube 14. Stated differently, the proximal edge 31 of the band 28 is positioned a first distance from the open proximal end 12 of the sample tube 14 and the distal edge 33 of the band 28 is positioned a second distance from the open proximal end 12, where the second distance is greater than the first distance, thereby defining a width.

The length L₁, or distance between the proximal edge 31 of the band 28 and the open proximal end 12 of the sample tube 14, can vary depending on, amongst others, the dimensions of the sample tube 14 and closure 10 associated with the sample tube. Generally, the length L₁ is in the range of about 0 mm to about 15 mm. In detailed embodiments, the length L₁ is greater than about 1 mm, 2 mm, 3 mm, 4 mm or 5 mm. In some embodiments, the length L₁ is less than about 14 mm, 13 mm, 12 mm, 11 mm, 10 mm, 9 mm, 8 mm, 7 mm or 6 mm. In various embodiments, the length L₁ is in the range of about 1 mm to about 10 mm, or in the range of about 2 mm to about 9 mm, or in the range of about 3 mm to about 8 mm, or in the range of about 4 mm to about 7 mm, or in the range of about 5 mm to about 7 mm, or in the range of about 6 mm to about 7 mm. In specific embodiments, the length L₁ is in the range of about 6.4 mm to about 6.5 mm.

The length L₃ (or width W) can vary depending on, amongst others, the length L₁, the sample tube 14 dimensions and the length L₂. In various embodiments, the length L3 (width W) of the band 28 is in the range of about 0.25 mm to about 5 mm or in the range of about 0.5 mm to about 4 mm, or in the range of about 0.75 mm to about 3 mm, or in the range of about 1 mm to about 2.5 mm. In specific embodiments, the width W of the band 28 is about 1.25 mm.

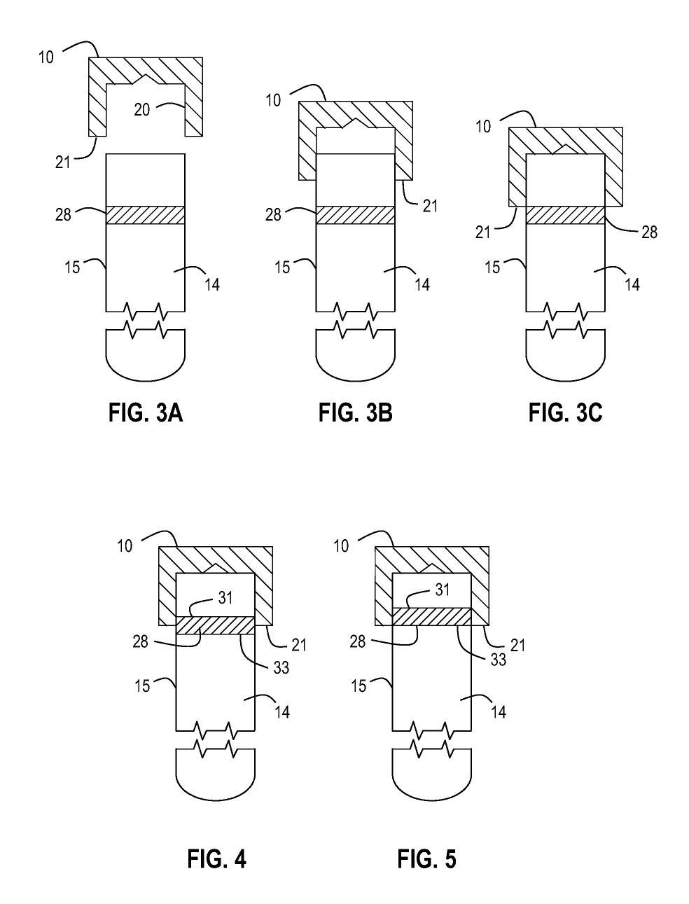

Additional embodiments of the invention are directed to methods of using an NMR tube. An exemplary method is embodied by FIGS. 3A to 3C. In FIG. 3A (also seen in FIG. 1), a closure 10 having a hollow bore 20 in the distal end 21 is placed over the open proximal end 12 of an NMR sample tube 14. The NMR sample tube 14 has an elongate cylindrical body 15 with a band 28 positioned adjacent the open proximal end 12. The hollow bore 20 of the closure 10 has a diameter about equal to or lesser than about the outside diameter of the elongate cylindrical body 15. As shown in FIG. 3B, a distally directed force is applied to the closure 10 to cause the hollow bore 20 to slide along the outside surface of the elongate cylindrical body 15. The closure 10 slides a length from the open proximal end 12 so that when the closure 10 is fully placed (shown in FIG. 3C) on the NMR sample tube 14, the distal end 21 of the closure 10 is within about the width W of the band.

As shown in the embodiment of FIG. 3C, after the closure 10 is fully placed on the elongate cylindrical body 15, the distal end 21 of the closure 10 is adjacent the proximal edge 31 of the band 28. A user can see that the closure 10 has been fully seated on the sample tube 14 when there is no space visible between the band 28 and the distal end 21 of the closure 10.

In the embodiment shown in FIG. 4, after the closure 10 is fully placed on the elongate cylindrical body 15, the distal end 21 of the closure 10 covers at least a portion of the band 28. In embodiments of this sort, the user can see that the closure 10 has been fully seated because there is no space visible between the band 28 and the distal end 21 of the closure and there is a portion of the band 28 remaining visible distally of the distal end 21 of the closure 10. This may be especially useful with thinner bands 28 or multicolor bands.

FIG. 5 shows another embodiment in which after the closure 10 is placed on the NMR sample tube 14, the distal end 21 of the closure 10 covers the entire band 28. The embodiment shown has the distal end 21 of the closure 10 a length along the elongate cylindrical body 15 about equal to the distal edge 33 of the band 28. A user will then be able to see that the closure is fully seated when there is no band 28 visible.

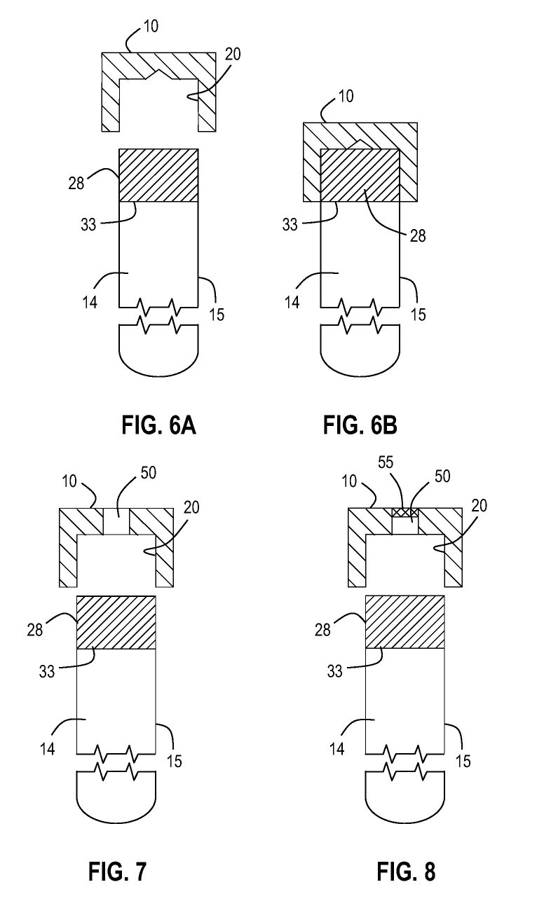

FIGS. 6A and 6B show alternate embodiments of the invention in which the proximal edge 31 of the band is about equal to the open proximal end 12 of the sample tube 14. In the embodiment shown, the band extends from the open proximal end 12 to a length along the sample tube 14. The length that the band extends may be the same as the depth of the hollow bore 20 in the closure so that when the closure 10 is fully seated on the sample tube 14, there is substantially no band 28 visible to the user.

Adding a sample to the tube can be accomplished in many ways using various devices, instruments and automated systems. In one or more embodiments, a sample is added to the NMR sample tube 14 before placing the closure 10 over the open proximal end 12 of the NMR sample tube 14. This is a common technique where the sample tube 14 is filled with sample prior to capping.

It is also possible to fill the sample tube 14 after placing the closure 10 over the open proximal end 12 of the sample tube 14. FIG. 7 shows another embodiment in which the closure has a opening 50 extending axially therethrough so that after the closure 10 has been fully placed onto the NMR sample tube 14, a sample can be placed into the sample tube 14 through the closure 10. FIG. 8 shows another embodiment in which the closure 10 has an opening 50 with a septum 55. The septum 55 can be made of the same material as the closure or from a different material. After a sample has been added to the sample tube 14, the tube 14 may be placed into a spinner (not shown) before or while placing the sample tube 14 into the NMR instrument.

In detailed embodiments, resistance to the distally directed force remains about constant throughout movement of the closure 10 along the elongate cylindrical body 15 from the open proximal end 12 until the closure 10 cannot be pushed further. This may be the case where the hollow bore 20 of the closure 10 has a substantially uniform profile (i.e., cylindrical). When the hollow bore 20 has a substantially uniform profile, the diameter of the hollow bore 20 is about equal to or lesser than the outside diameter of the NMR sample tube 14. If the fit of the closure 10 is too loose, the closure will not function properly. If the fit of the closure 10 is too tight, the closure will not readily slide on the sample tube 14 and may cause the sample tube 14 to break.

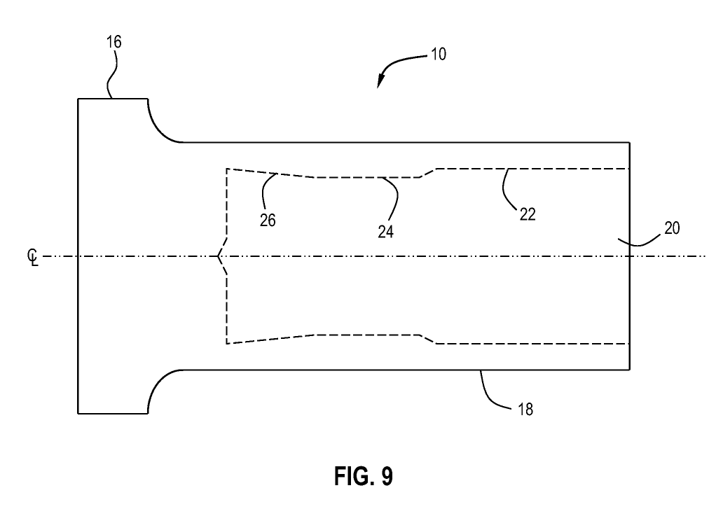

In specific embodiments, resistance to the distally directed force varies throughout pushing the closure 10 along the elongate cylindrical body 15 from the open proximal end 12 until the closure 10 cannot be pushed further. Variable resistance may be felt where the closure 10 has a hollow bore 20 with a non-uniform profile. FIG. 9 shows a specific embodiment of a selectively removable closure 10 for closing the open proximal end 12 of the NMR sample tube 14 is shown in which the variable resistance may be observed. The shape shown in FIG. 9 is merely illustrative and should not be taken as limiting the scope of the invention. The outer shape of the closure can be varied depending on, for example, the instrument and devices being used in conjunction with the sample tube. The closure 10 shown includes a cylindrical proximal first portion 16 and a distal second portion 18. Both portions 16 and 18 are substantially congruent to a central axis. The distal second portion 18 has a hollow bore 20 extending therethrough. The hollow bore 20 shown has three sections, a distal section 22, a central section 24 and a proximal section 26. Distal section 22 has an inside diameter sized to accept the outside diameter of a preselected size NMR sample tube substantially without an interference (e.g., the distal section 22 has an inside diameter greater than about the outside diameter of the sample tube 14. The central section 24 is sized to provide a compliant interference fit with the outside diameter of the preselected NMR sample tube and the proximal section 26 is sized to accept the outside diameter of the preselected NMR sample tube 14. By having the several I.D. dimensions of sections 22, 24 and 26 as described above, when closure 10 is distally axially inserted into the elongate cylindrical body 15, the distal section 22 guides sample tube 14 into the closure 10, the central section 24 provides a user perceptible resistance to passage of sample tube 14 and the movement of the sample tube 14 into proximal section 26 allows the user to perceive a lessened resistance to the movement of the sample tube 14 followed by seating the proximal end 12 of the sample tube 14 substantially adjacent first portion 16.

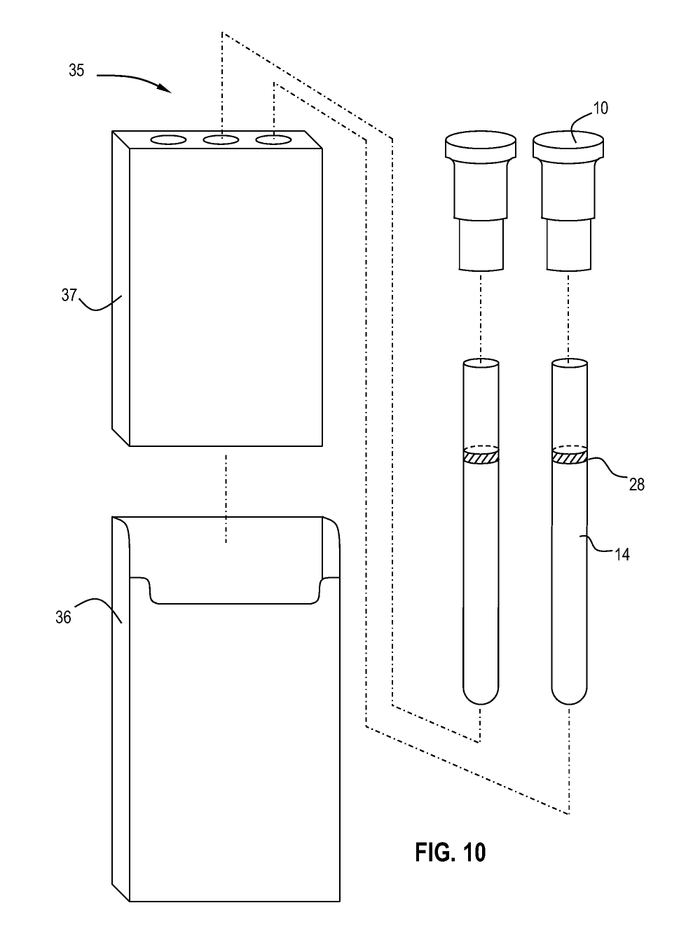

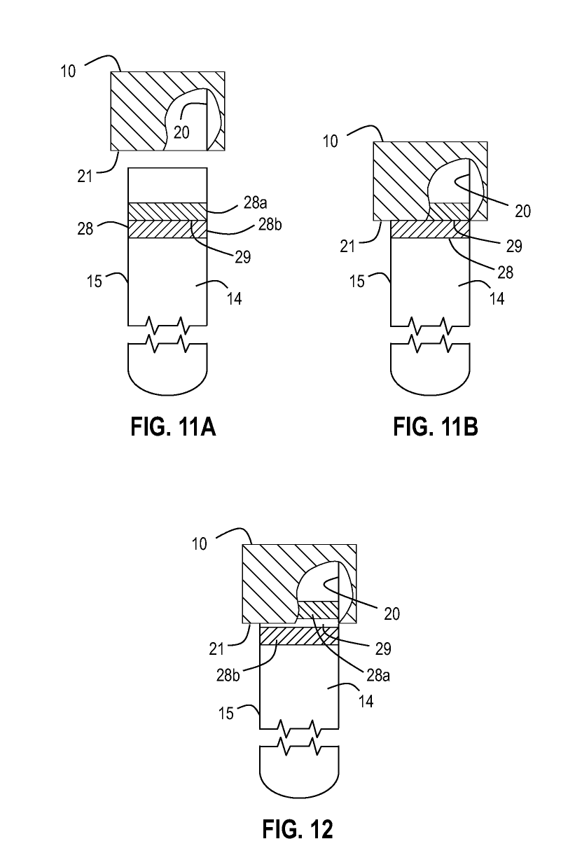

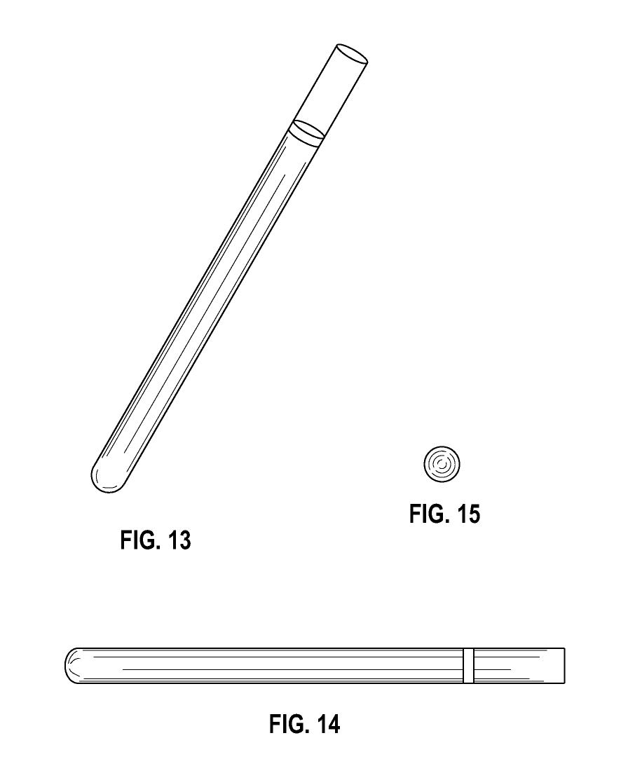

FIG. 10 shows another embodiment which is directed to a kit 35 comprising a package 36, at least one NMR sample tube 14 and at least one closure 10. The package 36 has a support structure 37 adapted to contain and separate elongate articles. The support structure 37 of some embodiments fits within the package 36 and may be integrally formed with the package 36. In specific embodiments, one or more of the package 36 and the support structure 37 are made of a cardboard material. The support structure 37 shown in FIG. 10 is inserted into the package 36, but other configurations are within the scope of the invention. A package top (not shown) may also be included to contain the elongate articles within the package 36. The kit 35 includes at least one sample tube 14 as described throughout. The kit 35 also includes at least one closure 10 configured to slidably engage the outside of an elongate cylindrical body 15.

The color of the closure 10 and the band 28 can be configured as desired. In some embodiments, the closure 10 and the band 28 have the same color. In detailed embodiments, the closure 10 has a different color than the band 28. This may help the user see the band when the closure 10 approaches the band 28, or slides over the band 28. In specific embodiments the closure is red and the band is white. In some embodiments, one or more of the closure and the band are blue.

FIGS. 11A and 11B show an embodiment in which the band 28 is multicolored (i.e., a combination of two bands adjacent each other). The multicolored band 28 shown in FIG. 11A has a proximal band 28a and a distal band 28b, but additional bands can be included. When the closure 10 is fully seated on the NMR sample tube 14, the distal end 21 of the closure 10 is positioned at the interface 29 of the proximal band 28a and distal band 28b. FIGS. 11A and 11B show a solid closure 10 with a window which is merely for illustrative purposes to visualize the covered proximal band 28a in FIG. 11B. It is not necessary for the distal end 21 of the closure 10 to be placed exactly at the interface 29, but may alert the user that the closure 10 is fully seated by covering nearly all or all of the proximal band 28a.

In another detailed embodiment, as shown in FIG. 12, the interface 29 may be a separation between the proximal band 28a and the distal band 28b. The separation shown in FIG. 12 is exaggerated for illustrative purposes. The separation may have a width in the range of about 0.1 mm to about 5 mm, depending on the size and diameter of the closure 10 and sample tube 14, and can be adjusted as needed. In detailed embodiments, the separation has a width in the range of about 0.2 mm to about 4 mm, or in the range of about 0.3 mm to about 3 mm, or in the range of about 0.4 mm to about 2 mm, or in the range of about 0.5 mm to about 1 mm.

In some embodiments of the closure of the invention, the closure may be formed from a solid rod of a polymeric material such as polytetrafluoroethylene (PTFE) or other substantially chemically inert materials having similar properties. The use of PTFE as a material is facilitated by shaping the rod into the desired dimensions with a computer numerical controlled (CNC) automated lathe apparatus. Once the CNC apparatus is properly set-up, it can repeatedly efficiently produce the closure of the invention with a high degree of accuracy and precision. For other applications, injection molding techniques using other polymeric materials may be utilized, but many polymeric materials suitable for injection molding may not have the same degree of solvent resistance and dimensional stability as PTFE. Additionally, PTFE has sufficient resiliency that the closure will deflect sufficiently at central portion 24 to allow for some variation in NMR tube outside diameter. For example, tubes of European manufacture may have a slightly larger nominal outside diameter for a particular size than tubes manufactured in North America.

NMR sample tubes 14 can be made from a variety of materials. Typically, sample tubes are formed from a vitreous material, generally various types of glass, e.g., soda-lime, borosilicate, quartz, and the like. In some applications, a polymeric material may also be used. The band 28 can be applied to any of the materials used in the manufacture of NMR tubes.

FIG. 13 shows a perspective view of a specific embodiment of an NMR sample tube. The band is shown without shading to represent a white color. However, other colors are possible and within the scope of the invention. FIG. 14 shows a side view of the NMR sample tube of FIG. 13. FIG. 15 shows a bottom view of the NMR sample tube.

In summary, in accordance with one of the aspects of the present invention, laboratory apparatus is provided. A NMR cylindrical tube having a closed end and an open end is provided. A cap having a hollow bore sized to fit securely over the open end of the NMR cylindrical tube is also provided. The NMR cylindrical tube has a band around the circumference of the NMR cylindrical tube. The band is positioned adjacent the open end of the NMR cylindrical tube such that when a top portion of the hollow bore of the cap touches the open end of the NMR cylindrical tube, at least a portion of the band is visible.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. In particular, those skilled in the art will know how to make appropriate changes to the dimensions of the below-described closure consistent with the invention and needs of the user. Thus, it is intended that the present invention include modifications and variations that are within the scope of the appended claims and their equivalents.

What is claimed is:

1. A method of using an NMR tube comprising:
placing a closure having a hollow bore in a distal end of the closure over an open proximal end of the NMR tube having an elongate cylindrical body with an outer diameter and a band around an outside surface of the elongate cylindrical body, the band having a width and placed near the open proximal end, the hollow bore being sized to fit over the outer diameter of the elongate body; and
applying distally directed force to the closure to cause the hollow bore to slide along the outside surface of the elongate cylindrical body a length from the open proximal end so that when the closure is fully placed on the NMR tube the distal end of the closure is within the width of the band.

2. The method of claim 1, wherein resistance to the distally directed force remains about constant throughout pushing the closure along the elongate cylindrical body from the open proximal end until the closure cannot be pushed further.

3. The method of claim 1, wherein resistance to the distally directed force varies throughout pushing the closure along the elongate cylindrical body from the open proximal end until the closure cannot be pushed further.

4. The method of claim 1, wherein after the closure is fully placed on the NMR tube, the distal end of the closure is adjacent a proximal edge of the band.

5. The method of claim 1, wherein after the closure is fully placed on the NMR tube, the distal end of the closure covers at least a portion of the band.

6. The method of claim 1, wherein after the closure is fully placed on the NMR tube, the distal end of the closure covers the entire band.

7. The method of claim 1, further comprising adding a sample to the NMR tube before placing the closure over the proximal open end of the NMR tube.

8. The method of claim 1, further comprising adding a sample to the NMR tube through an opening in the closure after the closure has been fully placed on the NMR tube.

9. The method of claim 1, further comprising placing the NMR tube into a sample spinner.

10. The method of claim 12, wherein the closure has a first color and the band has a second color, wherein the first color and the second color are different.

11. The method of claim 16, wherein the closure has a first color and the band has a second color, wherein the first color and the second color are the same.

12. A kit comprising:
a package having a support structure adapted to contain and separate elongate articles;
a plurality of NMR tubes positioned in the support structure, each of the plurality of NMR tubes comprising an elongate cylindrical body with an open proximal end and a band around an outside of the cylindrical body, the band positioned near the open proximal end and having a width extending along a length of the elongate cylindrical body; and
a closure on each of the plurality of NMR tubes, each of the closures configured to slidably engage the outside of the elongate cylindrical body so that when the closure is fully placed on one of the plurality of NMR tubes, a distal end of the closure extends a length along the cylindrical body and is within the width of the band.

13. The kit of claim 12, wherein when each closure is fully placed on one of the plurality of NMR tubes, the distal end of the closure is about equal to a proximal edge of the band.

14. The kit of claim 12, wherein when each closure is fully placed on one of the plurality of NMR tubes, the closure covers a portion of the band.

15. The kit of claim 12, wherein when each closure is fully placed on one of the plurality of NMR tubes, the distal end of the closure is about equal to a distal edge of the band.

16. The kit of claim 12, wherein each closure has a first color and the band on each of the plurality of NMR tubes has a second color that differs from the first color.

17. The kit of claim 16, wherein each closure has a first color and the band on each of the plurality of NMR tubes has a second color that is the same as the first color.

18. The kit of claim 12, wherein each closure further comprises an opening extending axially therethrough so that after the closure has been fully placed onto one of the plurality of NMR tubes, a sample can be placed into the NMR tube through the opening.

19. The kit of claim 18, wherein the opening comprises a septum.

20. Apparatus, comprising:
a NMR cylindrical tube having a closed end and an open end;
a cap having a hollow bore sized to securely fit over the open end of the NMR cylindrical tube;
a band around the outside of the NMR cylindrical tube, the band being positioned adjacent the open end of the NMR cylindrical tube such that when a top portion of the hollow bore of the cap touches the open end of the NMR cylindrical tube, at least a portion of the band is visible.
